(19) United States
(12) Patent Application Publication
(10) Pub. No.: US 2026/0334263 A1
(43) Pub. Date: Oct. 22, 2026

(54) ELECTRONIC DEVICE FEATURES FOR EVALUATION OF SINGULATION POSITIONING

(71) Applicant: Micron Technology, Inc., Boise, ID (US)

(72) Inventors: Kelvin Aik Boo Tan, Singapore (SG); Hong Wan Ng, Singapore (SG); Seng Kim Ye, Singapore (SG); See Hiong Leow, Singapore (SG); Chin Hui Chong, Singapore (SG)

(21) Appl. No.: 19/576,813

(22) Filed: Mar. 24, 2026

Related U.S. Application Data
(60) Provisional application No. 63/790,659, filed on Apr. 17, 2025.

(51) Int. Cl. H10W 70/65; H10W 70/05; H10W 74/00

(52) U.S. Cl. CPC H10W 70/657; H10W 70/096; H10W 74/00

(57) ABSTRACT

Methods, systems, and devices for electronic device features for evaluation of singulation positioning are described. Forming an electronic device may include forming a laminated substrate including a dielectric layer and a conductor layer. The conductor layer may include a bus portion along a singulation line, one or more contact portions extending from the bus portion, and one or more ground portions extending from the bus portion. The ground portion(s) may have a width dimension parallel to the singulation line that varies along a distance from the singulation line. The process may also include coupling a first electronic component with the laminated substrate. The process may also include forming a first electronic package and a second electronic package by dividing the laminated substrate between the first electronic component and the second electronic component.

### CROSS REFERENCE

The present Application for Patent claims priority to U.S. Patent Application No. 63/790,659 by Tan et al., entitled “ELECTRONIC DEVICE FEATURES FOR EVALUATION OF SINGULATION POSITIONING,” filed Apr. 17, 2025, which is assigned to the assignee hereof, and which is expressly incorporated by reference in its entirety herein.

### TECHNICAL FIELD

The following relates to one or more semiconductor systems including electronic device features for evaluation of singulation positioning.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. To form electronic packages (including memory dies) for memory devices, some manufacturing processes may include singulation procedures to divide a laminated substrate into one or more electronic packages.

### BRIEF DESCRIPTION OF THE DRAWINGS

FIG. 1 shows an example of a system that supports electronic device features for evaluation of singulation positioning in accordance with examples as disclosed herein.

FIG. 2A-2C show an example of a manufacturing process that supports electronic device features for evaluation of singulation positioning in accordance with examples as disclosed herein.

FIG. 3A-3D show an example of a manufacturing process that supports electronic device features for evaluation of singulation positioning in accordance with examples as disclosed herein.

FIG. 4 shows a flowchart illustrating a method or methods that support electronic device features for evaluation of singulation positioning in accordance with examples as disclosed herein.

### DETAILED DESCRIPTION

Some electronic systems (e.g., memory systems, processor systems, flip-chip die packages, a high bandwidth memory (HBM) system, 3D stacked memory systems) may include semiconductor systems (e.g., a die, a chip, a dynamic random access memory (DRAM) device) that are bonded (e.g., stacked, coupled, mounted) over a package substrate (e.g., a die substrate, a printed circuit board (PCB)). In some processes, electronic packages manufactured from a common substrate (e.g., a strip substrate) may be divided along a singulation line using a blade, such as in accordance with a narrow blade singulation (e.g., dividing a strip substrate between semiconductor systems to form package units). However, some manufacturing processes may result in relatively large blade shifts for blade singulation, which may result in issues with electronic packages during manufacturing. For example, blade shifts may result in failure to remove a portion of a plating bus bar (used for manufacturing) between the electronic packages (e.g., due to etching errors and capability limitations for different substrate suppliers). Accordingly, blade shifts may result in exposed conductive material (e.g., exposed metal, exposed copper, exposed plating bus bar, exposed conductive contact material). This exposed conductive material may be electrically floating, since the exposed conductive material may not be connected with a ground plane. Electrically floating conductor material may induce an antenna affect and may impact signal integrity for electronic packages, which may reduce performance or reliability of memory devices.

As described herein, a set of electronic packages may be formed to inhibit or prevent electrically floating metal and to support verification of whether the set of electronic packages are usable or reliable. For example, to form an electronic package, a process (e.g., a manufacturing process) may include forming a laminated substrate (e.g., a printed circuit board (PCB) substrate) including a dielectric layer and a conductor layer. The conductor layer may include a bus portion (e.g., a plating bus) along a singulation line, one or more contact portions extending from the bus portion on a first side of the singulation line, and one or more ground portions extending from the bus portion on the first side of the singulation line. The bus portion, the contact portion(s), and the ground portion(s) may be formed of a continuous conductor material (e.g., copper, a copper layer of the laminated substrate). Each ground portion may have a width dimension parallel to the singulation line that varies along a distance from the singulation line.

The process may also include coupling a first electronic component (e.g., a semiconductor component, a die, a die stack, a die assembly) with the laminated substrate on the first side of the singulation line. For example, the process may include coupling circuitry of the first electronic component with a respective contact of each of the one or more contact portions. Similarly, the process may include coupling a second electronic component with the laminated substrate on a second side of the singulation line. Subsequently, the process may include forming a first electronic package and a second electronic package by dividing (e.g., cutting, singulating) the laminated substrate between the first electronic component and the second electronic component. The respective contact of each contact portion may be electrically isolated from the ground portion(s) in the first electronic package (e.g., based on dividing the electronic packages). Accordingly, the first electronic package and the second electronic package may include electrically grounded indicator features (e.g., the ground portions(s)) that indicate a location of division between the packages relative to the singulation line (e.g., indicating whether the electronic packages are reliable or usable). Such techniques may support preventing excess floating metal by removing the entire bus portion and, in some examples, etching back the contact portions (e.g., prior to the singulation procedure, during an etching back process).

In addition to applicability in memory systems as described herein, techniques for electronic device features for evaluation of singulation positioning may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving an evaluation of manufactured parts, which may result in reduced electronic waste and may extend the life of electronic devices, among other benefits.

Features of the disclosure are illustrated and described in the context of systems and architectures. Features of the disclosure are further illustrated and described in the context of manufacturing processes and flowcharts.

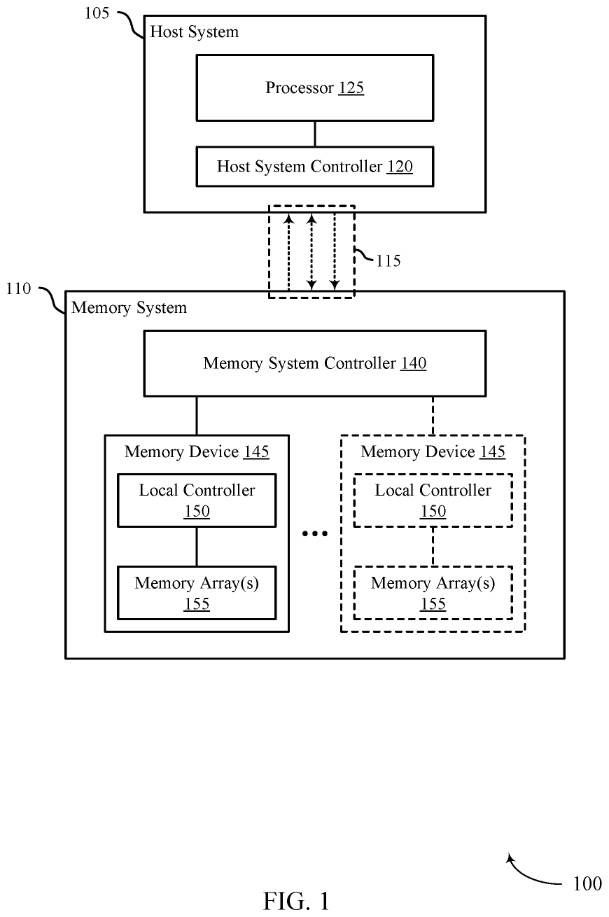

FIG. 1 shows an example of a system 100 that supports electronic device features for evaluation of singulation positioning in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a semiconductor system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host system 105, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some systems 100 may include one or more semiconductor systems (e.g., a set of one or more dies, a set of one or more chips, of a memory system 110 or portion thereof, or a host system 105 or portion thereof) that are soldered to a package substrate (e.g., a die substrate, a PCB substrate). A set of electronic packages (e.g., each package including one or more semiconductor systems soldered with a package substrate) may be formed to inhibit or prevent electrically floating metal and to support verification of whether the set of electronic packages are usable or reliable. For example, to form an electronic package, a process (e.g., a manufacturing process) may include forming a laminated substrate (e.g., a PCB substrate) including a dielectric layer and a conductor layer. The conductor layer may include a bus portion (e.g., a plating bus) along a singulation line, one or more contact portions extending from the bus portion on a first side of the singulation line, and one or more ground portions extending from the bus portion on the first side of the singulation line. The bus portion, the contact portion(s), and the ground portion(s) may be formed of a continuous conductor material (e.g., copper, a copper layer of the laminated substrate). Each ground portion may have a width dimension parallel to the singulation line that varies along a distance from the singulation line.

The process may also include coupling a first electronic component (e.g., a semiconductor component, a die, a die stack, a die assembly) with the laminated substrate on the first side of the singulation line. For example, the process may include coupling circuitry of the first electronic component with a respective contact of each of the one or more contact portions. Similarly, the process may include coupling a second electronic component with the laminated substrate on a second side of the singulation line. Subsequently, the process may include forming a first electronic package and a second electronic package by dividing (e.g., cutting, singulating) the laminated substrate between the first electronic component and the second electronic component. The respective contact of each contact portion may be electrically isolated from the ground portion(s) in the first electronic package (e.g., based on dividing the electronic packages). Accordingly, the first electronic package and the second electronic package may include electrically grounded indicator features (e.g., the ground portions(s)) that indicate a location of division between the packages relative to the singulation line (e.g., indicating whether the electronic packages are reliable or usable). Such techniques may support preventing excess floating metal by removing the entire bus portion and, in some examples, etching back the contact portions (e.g., prior to the singulation procedure, during an etching back process).

The techniques described herein may support an etch-back opening window to remove a plating line. Further, in some cases, techniques described herein may include a unique conductor feature, which may be electrically grounded (e.g., a unique ground feature, a ground portion) to a package substrate common ground (e.g., to replace a plating bus bar). Such techniques may enable use of a narrow saw width (e.g., fine saw width), which may reduce a cost per package in manufacturing electronic packages (e.g., generating more packages within a strip of laminated substrate material). Further, such techniques may reduce exposed copper at a package sidewall (e.g., eliminating oxidation due to copper exposed to the air). As described herein, the unique conductor feature (e.g., unique ground feature) may support techniques for detecting and preventing package errors. For example, a blade shift that satisfies (e.g., exceeds) a threshold value (e.g., an allowable value) during singulation may be detectable. In some cases, the techniques described herein may eliminate a risk of electrically floating metal (e.g., floating copper bar) on a package side wall (e.g., preventing an antenna effect within the package). Such techniques may also improve an electrostatic discharge (ESD) optimization, including configurations in which the unique feature is close to a wire bond finger.

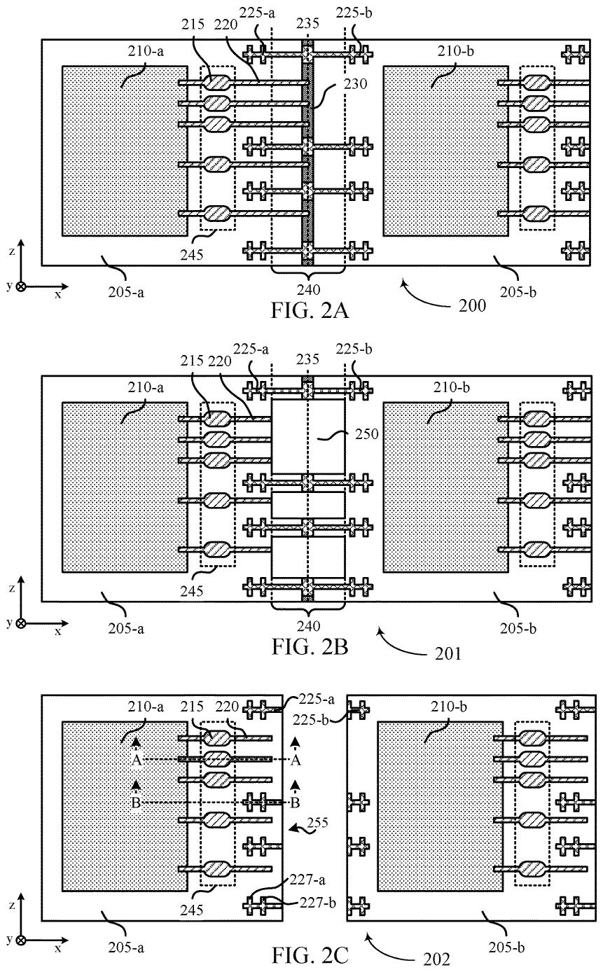

FIG. 2A-2C show an example of a manufacturing process that supports electronic device features for evaluation of singulation positioning in accordance with examples as disclosed herein. The manufacturing process includes multiple phases to form a first electronic package 205-a and a second electronic package 205-b by dividing a laminated substrate. In some cases, as described herein, the electronic package 205-a and the electronic package 205-b may be referred to as electronic components, and vice versa (e.g., before or after singulation). For example, the electronic package 205-a may include a first electronic component 210-a (e.g., a semiconductor component, a semiconductor assembly, a memory die, a chip). In some implementations, the manufacturing process may include forming multiple electronic packages (e.g., two or more) from a single laminated substrate (e.g., a strip substrate) in accordance with techniques described herein.

FIG. 2A shows an example of a first phase 200 of the manufacturing process. In the first phase 200, the manufacturing process may include forming or providing a laminated substrate (e.g., a printed circuit board (PCB)) comprising a dielectric layer (e.g., a composite material, a fiberglass material, an FR-4 material) and a conductor layer (e.g., a copper layer). The conductor layer may include a bus portion 230 (e.g., a plating bus bar, a plating bus) along a singulation line 235 (e.g., along the z-direction, a package singulation line, a line of division), one or more contact portions 220 (e.g., plating lines) extending from the bus portion 230 on a first side of the singulation line 235 (e.g., a side along the negative x-direction, extending along the negative x-direction), and one or more ground portions 225-a (e.g., a unique ground feature) extending from the bus portion 230 on the first side of the singulation line 235. In some examples, a ground portion 225-a may have a width dimension parallel to the singulation line 235 (e.g., along the z-direction) that varies along a distance from the singulation line 235 (e.g., on the first side of the singulation line 235, along the x-direction). The bus portion 230, the contact portions 220, and the ground portions 225-a may be formed of a continuous conductor material (e.g., copper, of a copper layer of a PCB substrate).

In some implementations, the conductor layer of the laminated substrate also may include one or more ground portions 225-b extending from the bus portion 230 on a second side of the singulation line 235 (e.g., a side along the positive x-direction, extending along the positive x-direction). Where applicable, ground portions 225-b may be formed of the same continuous conductor material. In some examples, a ground portions 225-b also may have a width dimension parallel to the singulation line 235 that varies along a distance from the singulation line 235 (e.g., along the x-direction, on the second side of the singulation line 235).

In some implementations, the manufacturing process may include forming a solder mask over the laminated substrate, which may be formed with one or more openings 245 over a respective contact 215 of each contact portion 220. In some cases, the manufacturing process may include plating contact(s) 215 with a second conductor material (e.g., a nickel gold bath) based on applying a voltage to the bus portion 230. For example, plating of the respective contact 215 may be performed through opening(s) 245 in the solder mask (e.g., avoiding plating of areas of contact portions 220 that are underneath the solder mask material). After the plating, the manufacturing process may include coupling the electronic component 210-a with the laminated substrate.

As described herein, the aspect of “a width dimension varying along a distance from the singulation line” (e.g., of ground portion(s) 225-a and, where appliable, ground portion(s) 225-b) may refer to a form (e.g., shape, pattern) of the ground portions as illustrated in FIG. 2A-2C (e.g., when viewed along the y-direction). For example, for at least one ground portion 225-a, the width dimension varying along the distance from the singulation line 235 may refer to one or more first portions of the ground portion 225-a having a first width (e.g., along the z-direction) along a respective first length (e.g., distance, along the x-direction) from the singulation line 235. Further, such varying may refer to one or more second portions (e.g., portions 227) of the one or more ground portions 225-a having a second width, greater than the first width, along a respective second length (e.g., distance) from the singulation line 235. Accordingly, different portions of a ground portion 225-a may have different widths with respect to a distance from the singulation line 235. Similarly, for at least one ground portion 225-b, a width dimension varying along the distance from the singulation line 235 may refer to one or more third portions having a third width along a respective third length from the singulation line 235 and one or more fourth portions having a fourth width, greater than the third width, along a respective fourth length from the singulation line 235.

Accordingly, each ground portion 225 may include multiple portions (e.g., along the x-direction), each having a respective width (e.g., along the z-direction). For example, a first ground portion 225-a may include a first conductive path that is non-parallel (e.g., perpendicular) to the singulation line 235. The first ground portion 225-a may also include one or more second conductive paths (e.g., portions 227, such as portions 227-a and 227-b) that are non-parallel (e.g., perpendicular) to the first conductive path (e.g., to form a crossing shape of conductive material). One or more first portions of the first ground portion 225-a may have a first width that is equal to a width of the first conductive path. For example, the one or more first portions of the first ground portion 225-a may be portions of the first conductive path that do not cross with the one or more second conductive paths, and thus may have the first width equal to the width of the first conductive path. One or more second portions of the first ground portion 225-a may be portions of the first conductive path that cross with the one or more second conductive paths, and thus may have a second width equal to a length of the one or more second conductive paths (e.g., greater than the first width). The second portion(s) of the first ground portion 225-a may be referred to as “tails” of the first ground portion 225-a (e.g., in the context of “counting tails” to determine a position of dividing in relation to the singulation line 235 after singulation). Although two “tails” are shown for the illustrative first ground portion 225-a, more or fewer “tails” may be used in accordance with techniques as described herein. The first and second widths may be according to a width dimension of the first ground portion 225-a, the width dimension parallel to the singulation line 235 (e.g., along the z-direction). Accordingly, in accordance with these and other examples, a first ground portion 225-a may have a width dimension, parallel to the singulation line 235, that varies along a distance from the singulation line 235.

In some implementations, before dividing the laminated substrate between the electronic package 205-a and the electronic package 205-b, the laminated substrate may include a second conductor layer, opposite the dielectric layer from the conductor layer (e.g., opposite along the y-direction, on a back side of the laminated substrate depicted in FIG. 2A, not illustrated). The second conductor layer may include one or more third ground portions 225 extending from the bus portion 230 on the first side of the singulation line 235, one or more fourth ground portions extending from the bus portion 230 on the second side of the singulation line 235, or both. The one or more third ground portions and the one or more fourth ground portions may be formed of a second continuous conductor material (which may be a same material as the first continuous conductive material, but on an opposite side of the dielectric layer). Each third ground portion 225 may have a width dimension parallel to the singulation line 235 that varies along a distance from the singulation line 235, and each fourth ground portions 225 may have a width dimension parallel to the singulation line 235 that varies along a distance from the singulation line 235.

FIG. 2B shows an example of a second phase 201 of the manufacturing process. In the second phase 201, the manufacturing process may include forming one or more openings 250 (e.g., holes) through the laminated substrate along the singulation line 235 (e.g., positioned over the singulation line 235). Edges of opening(s) 250 may be at an outline of the electronic package 205-a and the electronic package 205-b. Formation of opening(s) 250 may remove a respective portion of the bus portion 230 (e.g., a respective portion between pairs of ground portions 225-a). Removing respective portions of the bus portion 230 may include breaking the bus portion 230 (e.g., dividing the plating bus bar). In some examples, ground portion(s) 225-a may be located between openings 250. In some cases, forming the opening(s) 250 may electrically isolate a respective contact 215 of contact portion(s) 220 from ground portion(s) 225-a, 225-b, or both.

In some examples, the manufacturing process may include performing a material removal operation (e.g., an etching operation, a recessing operation) through opening(s) 250. The material removal operation may recess (e.g., along the x-direction) the contact portion(s) 220 from one or more sidewalls (e.g., in yz-planes, among other sidewall orientations) of the opening(s) 250. For example, the material removal operation may etch away (e.g., remove) material from contact portion(s) 220 such that contact portion(s) 220 do not extend to sidewalls of the opening(s) 250 (e.g., such that the contact portion(s) 220 have an extent that is at least threshold distance from the one or more sidewalls). Accordingly, contact portion(s) 220 may not be in contact with a singulation apparatus (e.g., a saw) during a singulation operation. Further, the contact portion(s) 220 may remain electrically isolated from ground portion(s) 225 in accordance with the material removal operation (e.g., even after a shielding operation).

Additionally, or alternatively, the contact portion(s) 220 may extend to the one or more sidewalls of the opening(s) 250. For example, the material removal operation may recess the contact portion(s) 220 such that the contact portions extend to the one or more sidewalls (and no further, in some cases). As such, the material removal operation may remove at least a portion of the contact portion(s) 220 that overlap with the opening(s) 250, as illustrated in FIG. 2B. In some examples, forming the opening(s) 250 may remove portions of the contact portion(s) 220 that overlap with regions corresponding to the opening(s) 250.

In some cases, the manufacturing process may include removing a respective portion of contact portion(s) 220 along the singulation line 235. The respective contact 215 of each contact portion 220 may be electrically isolated from the ground portion(s) 225 based on removing the respective portion of contact portion(s) 220. In some implementations, the manufacturing process may include forming a mold compound (e.g., an epoxy mold compound (EMC)) over the laminated substrate (e.g., and over the electronic components 210, before dividing the laminated substrate). The mold compound may fill opening(s) 250 and cover one or more sidewalls (e.g., exposed sidewalls, sidewalls recessed between the solder mask and dielectric material) of the contact portion(s) 220.

FIG. 2C shows an example of a third phase 202 of the manufacturing process. In the third phase 202, the manufacturing process may include coupling an electronic component 210-a (e.g., a first chip, a first chip assembly, a first semiconductor component) with the laminated substrate on the first side of the singulation line 235. Coupling the electronic component 210-a with the laminated substrate may include coupling circuitry of the electronic component 210-a with contact(s) 215 (e.g., performing a wire bonding between the electronic component 210-a and the contact(s) 215, soldering the electronic component to the contact(s) 215). The manufacturing process may similarly include coupling a second electronic component 210-b with the laminated substrate on a second side of the singulation line 235 (e.g., with other contacts 215).

The manufacturing process may also include forming the electronic package 205-a and the electronic package 205-b by dividing the laminated substrate between the electronic component 210-a and the electronic component 210-b. After such a division, contact(s) 215 may be electrically isolated from ground portions 225-a in the electronic package 205-a. The electronic package 205-b may include respective portions of ground portion(s) 225-b based on the division. In some cases, the division may include a cutting operation using a blade (e.g., a saw blade) having a width that is less than a threshold (e.g., minimum) distance between second portions (e.g., wider portions) of ground portion(s) 225-a and fourth portions (e.g., wider portions) of ground portions 225-b (e.g., a threshold distance of 50 to 100 micrometers from a package edge). For example, the width of the blade may allow the electronic package 205-a to retain at least one wider portion of a contact portion 225-a and the electronic package 205-b to retain at least one wider portion of a contact portion 225-b. In some examples, the blade may have a width (e.g., kerf) that is less than or equal to a width 240. The width 240 may be a width of opening(s) 250.

In some implementations, the electronic package 205-a may include a quantity of relatively wider portions of ground portion(s) 225-a. The quantity of the wider portions remaining in the electronic package 205-a after dividing the laminated substrate may indicate a first extent of the dividing relative to the singulation line 235. Additionally, or alternatively, the electronic package 205-a may include a quantity of relatively wider portions of ground portion(s) 225-b. The quantity of the wider portions remaining in the electronic package 205-b after dividing the laminated substrate may indicate another extent of the dividing (e.g., relative to respective contacts 215 of the electronic package 205-b). In some cases, dividing the laminated substrate may include removing a respective portion of ground portion(s) 225-a. A respective width of ground portion(s) that remain after the division may indicate a location of the dividing relative to the singulation line 235.

In some implementations, the ground portion(s) 225-a on the electronic package 205-a may be wider (e.g., in an x-dimension) than the ground portion(s) 225-b on the electronic package 205-b. This difference in width may be a result of a blade shift during a singulation process to divide the electronic package 205-a and the electronic package 205-b. In some cases, the electronic package 205-b may include additional ground portion(s) 225 (e.g., on a right side of the electronic package 205-b). The additional ground portion(s) 225 may be a result of another singulation operation that divides the electronic package 205-b from a third electronic package 205. The third electronic package may have a quantity of ground portion(s) 225 that are narrower (e.g., in the x-dimension) than the additional ground portion(s) 225 on the electronic package 205-b, which may be an indication of a second singulation line associated with dividing the electronic package 205-b and the third electronic package 205.

Additionally, or alternatively, the electronic package 205-a may include a quantity of contact portion(s) 220 that extend to point a threshold distance from a sidewall of the electronic package 205-a. For example, a contact portion 220 on the electronic package 205-a may extend such that the contact portion 220 overlaps with at least one ground portion in an x-dimension (but not in a y-dimension, as shown). In some cases, the contact portion 220 on the electronic package 205-a may extend past one or more “tail” portions of the ground portion(s). Similarly, the electronic package 205-b may include a quantity of contact portion(s) 220 that extend to point a threshold distance from a sidewall of the electronic package 205-a and extend past one or more “tail” portions of the ground portion(s).

In some cases (e.g., if the laminated substrate includes the second conductive layer), the electronic package 205-a may include respective portions of third ground portion(s) 225 based on dividing the laminated substrate between the electronic component 210-a and the electronic component 210-b. Similarly, the electronic package 205-b may include respective portions of fourth ground portion(s) 225 based on dividing the laminated substrate between the electronic component 210-a and the electronic component 210-b.

The electronic package 205-a depicted in FIG. 2C may illustrate a cross section of a finished electronic package implementing techniques as described herein. The electronic package 205-a may include a laminated substrate. The laminated substrate may include a dielectric layer and a conductor layer. The conductor layer may include one or more contacts 215 and one or more ground portions 225-a extending from a sidewall 255 of the laminated substrate. The sidewall 255 may be a portion of a package outline of the electronic package 205-a. The contact(s) 215 may be electrically isolated from the ground portion(s) 225-a. Each ground portion 225-a may have a width dimension, parallel to the sidewall 255 (e.g., along the z-direction), that varies along a distance from the sidewall 255 (e.g., along the x-direction). The electronic package 205-a may include the electronic component 210-a (e.g., a memory die) coupled with the laminated substrate. Circuitry of the electronic component 210-a may be coupled with contact(s) 215 (e.g., via a wire bond with the one or more contacts 215).

In some cases, a width of ground portion(s) 225-a may indicate a location of singulation of the electronic package 205-a. For example, if the ground portion(s) 225-a has a width that in increases or decreases (e.g., in a continuous manner, in a stepwise manner) along a dimension from a sidewall 255 (e.g., along the x-direction), a width that satisfies a threshold (e.g., is within a width range) may indicate that the singulation (e.g., dividing) was successful, and that the electronic package 205-a is reliable or usable for memory devices. In some other examples, a singulation that cuts through (e.g., forms a sidewall 255 along) a relatively narrower portion of a ground portion 225 may indicate a successful singulation, whereas a singulation that cuts through a relatively wider portion of a ground portion may indicate an unsuccessful singulation (e.g., with an unacceptable amount of blade shift).

Additionally, or alternatively, the manufacturing system may determine the location of singulation based on a shape of ground portion(s) 225-a. For example, for at least one of the ground portions 225, the width dimension that varies along the distance from the sidewall may be associated with one or more first portions having a relatively smaller width and one or more second portions having relatively larger width. In such cases, a manufacturing system 110 may determine an extent of a cutting operation (e.g., singulation) associated with forming the sidewall 255 based on a quantity of the first portions, a quantity of the second portions, or both in the electronic package 205-a. In some cases, techniques associated with the ground portion(s) 225-a may be applied to a respective sidewall 255 along each side of the electronic package 205-a (e.g., other sidewalls of the first electronic package).

In some implementations, contact(s) 215 may be associated with a conductor material that is recessed behind sidewalls 255 (e.g., outer walls) of the laminated substrate. The electronic packages 205 may include a mold compound (e.g., EMC, not shown) formed over the laminated substrate. The mold compound may be in contact with the conductor material (e.g., of the one or more contacts 215). In some cases, the electronic package 205-a may include a shielding layer over the mold compound, and the shielding layer may be coupled with (e.g., in contact with) ground portion(s) 225-a (e.g., and not with contact(s) 215). In accordance with these and other examples, ground portion(s) 225 may be coupled with a ground node of an electronic package 205, which may prevent ground portion(s) 225 from being electrically floating, reducing or eliminating an antenna effect that may reduce performance of the electronic package 205.

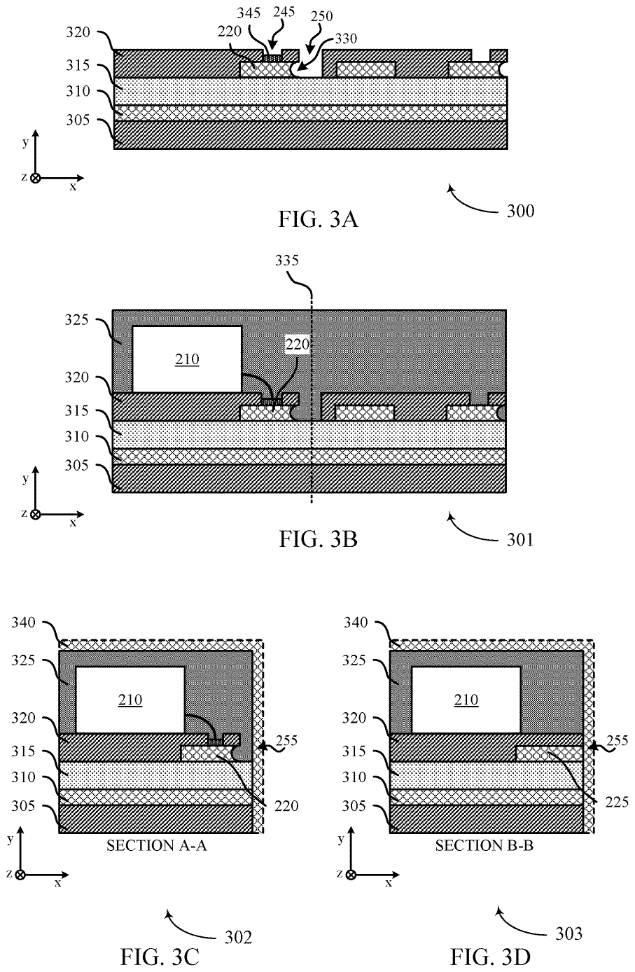

FIG. 3A-3D shows an example of a manufacturing process that supports electronic device features for evaluation of singulation positioning in accordance with examples as disclosed herein. The manufacturing process in the following description may be similar to (e.g., a portion of) the manufacturing process described with reference to FIG. 2A-2C, and may illustrate a side-view of the laminated substrate and electronic packages described herein.

FIG. 3A shows an example of a first phase 300 of the manufacturing process. In the first phase, the manufacturing process may include forming or providing a dielectric layer 305, a conductor layer 310 (e.g., a copper layer), and a core layer 315 (e.g., a non-conductive substrate forming a foundation of the laminated substrate). In some cases, the manufacturing process may include forming one or more contact portions 220 (e.g., as described with reference to FIG. 2A). In some implementations, the laminated substrate depicted in FIG. 3A may be referred to as an incoming substrate (e.g., a provided package substrate, from a substrate manufacturer, prior to package assembly).

In some examples, the manufacturing process may include forming a solder mask 320 over the core layer (e.g., the dielectric layer) and contact portion(s) 220, which may include one or more openings 245 over the contact portion(s) 220 (e.g., to allow access to contact(s) 215). In some implementations, the manufacturing process may include forming one or more openings 250 (e.g., etch back openings) through the solder mask 320 (and one or more other layers, where applicable). In some cases, the manufacturing process may include removing a respective portion of each contact portion 220 (e.g., along a singulation line 235). Each contact portion 220 may be electrically isolated from ground portion(s) 225 based on removing the respective portion of the contact portion 220 to form a cavity 330 (e.g., a recess). For example, a portion of each contact portion 220 may be removed such that the contact portion(s) 220 do not extend to a sidewall of opening(s) 250 (e.g., as illustrated). Although the cavity 330 may be illustrated as a semi-circle cavity in FIG. 3A, other shapes may result from such recessing. In accordance with these and other examples, forming cavities 330 may inhibit or prevent contact portion(s) 220 from extending to the sidewall of opening(s) 250, which may support electrical isolation of contact portion(s) 220.

In some cases, the manufacturing process may include plating contact portion(s) 220 with a conductor material 345 based on applying a voltage to a bus portion 230 (e.g., as described with reference to FIG. 2A). For example, plating of contact portion(s) 220 may be performed through opening(s) 245 in the solder mask 320. After the plating, the manufacturing process may include coupling one or more electronic components 210 with the laminated substrate as described with reference to FIG. 2A.

FIG. 3B shows an example of a second phase 301 of the manufacturing process. In the second phase, the manufacturing process may include forming a mold compound 325 (e.g., EMC) over the laminated substrate (e.g., before dividing the laminated substrate, over electronic component(s) 210, after bonding electronic component(s) 210 with the laminated substrate, such as by way of wire bonding or other coupling), which may fill the opening(s) 250. The mold compound 325 may cover one or more sidewalls (e.g., exposed sidewalls) of the contact portion(s) 220. For example, the mold compound 325 may fill the opening(s) 250 and the cavit(ies) 330 (e.g., formed by recessing contact portion(s) 220 in the first phase).

In some implementations, the manufacturing process may include dividing the laminated substrate into a first electronic package and a second electronic package along a dividing line 335 (e.g., performing a singulation process). The dividing line 335 may correspond to (e.g., be coplanar with) the singulation line 235 as described with reference to FIG. 2A-2C. This dividing may result in at least the first electronic package illustrated in cross sections by FIGS. 3C and 3D, and as described with reference to FIG. 2C.

FIG. 3C shows an example of a cross section 302 of the first electronic package after a third phase of the manufacturing process. The cross section 302 may be along a section A-A (e.g., in an xy-plane) as illustrated in FIG. 2C. In some cases, the solder mask 320 may not extend to a sidewall 255 in the cross section 302. In some other cases (not shown), the solder mask 320 may extend to a sidewall 255 of the first electronic package in the cross section 302. Additionally, or alternatively, a portion of the mold compound 325 may separate the solder mask 320 from the sidewall 255. In accordance with these and other examples, the contact portion(s) 220 may not extend to the sidewall (e.g., may be covered by the mold compound 325).

In some implementations, in the third phase, the manufacturing process may include forming, over the mold compound 325, a conductive material 340 (e.g., a conductive shielding layer) over the mold compound 325. The conductive material 340 may not be coupled with contact portion(s) 220, which may be based at least in part on a recess operation that forms cavit(ies) 340. Such a separation may support contact portion(s) 220 being electrically isolated from one another and from ground portion(s) 225.

FIG. 3D shows an example of a cross section 303 of the first electronic package after the third phase of the manufacturing process. The cross section 302 may be along a section B-B (e.g., in an xy-plane) as illustrated in FIG. 2C. As shown, the conductive material 340 may be coupled with sidewalls of ground portion(s) 225 that are exposed based on the dividing. The ground portion(s) 225 also may be coupled with a ground node (e.g., of the electronic component 210, of an electronic package 205 that includes the electronic component 210). Thus, the conductive material 340 also may be electrically grounded, which may support a shielding functionality of the conductive material 340 (e.g., shielding electromagnetic noise to or from the electronic component 210).

As described herein, contacts portion(s) 220 may be electrically isolated from ground portion(s) 225. Each ground portion 225 may have a width dimension, parallel to a sidewall 255 of a laminated substrate (e.g., along the z-direction), that varies along a distance from the sidewall 255 (e.g., along the x-direction). An electronic package 205 may include an electronic component 210 (e.g., a memory die) coupled with the laminated substrate. Circuitry of the electronic component 210 may be coupled with each contact portion 220 (e.g., via a wire bond or solder with the contact portion(s) 220).

A respective width of ground portion(s) 225 may indicate a location of singulation of an electronic package 205 (e.g., relative to a dividing line 335, along the x-direction). For example, if ground portion(s) 225 have a width that satisfies a threshold (e.g., is greater than a threshold, is less than a threshold, is within a threshold range), a manufacturing system may determine that the singulation (e.g., dividing) was successful, and that the electronic package 205 is reliable or usable for use. Additionally, or alternatively, a manufacturing system may determine the location of singulation based on a shape of one or more ground portions 225. For example, for at least one ground portion 225, a width dimension that varies along a distance from a sidewall may be associated with one or more relatively narrower first portions and one or more relatively wider second portions. In such cases, a manufacturing system may determine an extent of a cutting operation (e.g., singulation) associated with forming sidewall(s) 255 based on a quantity of the first portions, a quantity of the second portions, or both in the associated electronic package 205.

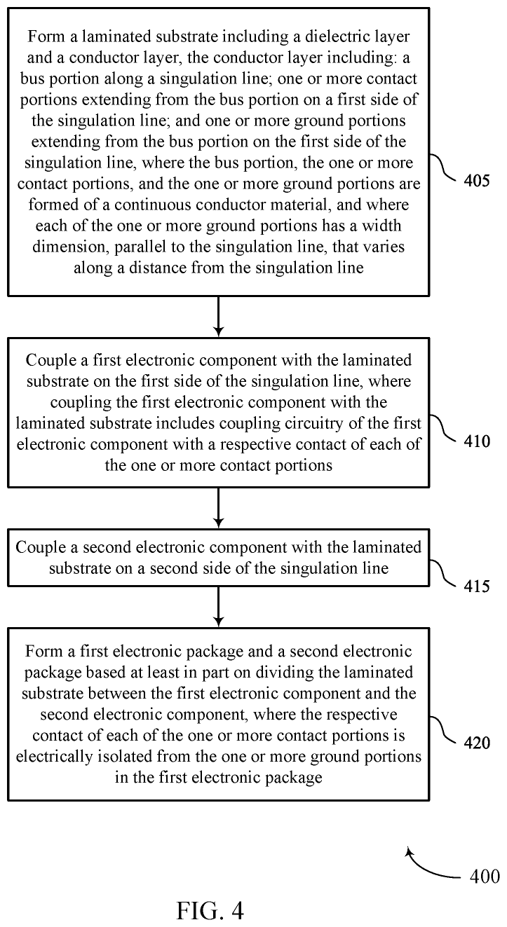

FIG. 4 shows a flowchart illustrating a method 400 that supports electronic device features for evaluation of singulation positioning in accordance with examples as disclosed herein. The operations of method 400 may be implemented by a manufacturing system or its components as described herein. For example, the operations of method 400 may be performed by a manufacturing system as described with reference to FIGS. 1 through 3D. In some examples, a manufacturing system may execute a set of instructions to control the functional elements of the device to perform the described functions. Additionally, or alternatively, the manufacturing system may perform aspects of the described functions using special-purpose hardware.

At 405, the method 400 may include forming (e.g., or providing) a laminated substrate including a dielectric layer and a conductor layer, the conductor layer including: a bus portion along a singulation line; one or more contact portions extending from the bus portion on a first side of the singulation line; and one or more ground portions extending from the bus portion on the first side of the singulation line, where the bus portion, the one or more contact portions, and the one or more ground portions are formed of a continuous conductor material, and where each of the one or more ground portions has a width dimension, parallel to the singulation line, that varies along a distance from the singulation line.

At 410, the method 400 may include coupling a first electronic component with the laminated substrate on the first side of the singulation line, where coupling the first electronic component with the laminated substrate includes coupling circuitry of the first electronic component with a respective contact of each of the one or more contact portions.

At 415, the method 400 may include coupling a second electronic component with the laminated substrate on a second side of the singulation line.

At 420, the method 400 may include forming a first electronic package and a second electronic package based at least in part on dividing the laminated substrate between the first electronic component and the second electronic component, where the respective contact of each of the one or more contact portions is electrically isolated from the one or more ground portions in the first electronic package.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming or providing a laminated substrate including a dielectric layer and a conductor layer, the conductor layer including: a bus portion along a singulation line; one or more contact portions extending from the bus portion on a first side of the singulation line; and one or more ground portions extending from the bus portion on the first side of the singulation line, where the bus portion, the one or more contact portions, and the one or more ground portions are formed of a continuous conductor material, and where each of the one or more ground portions has a width dimension, parallel to the singulation line, that varies along a distance from the singulation line; coupling a first electronic component with the laminated substrate on the first side of the singulation line, where coupling the first electronic component with the laminated substrate includes coupling circuitry of the first electronic component with a respective contact of each of the one or more contact portions; coupling a second electronic component with the laminated substrate on a second side of the singulation line; and forming a first electronic package and a second electronic package based at least in part on dividing the laminated substrate between the first electronic component and the second electronic component, where the respective contact of each of the one or more contact portions is electrically isolated from the one or more ground portions in the first electronic package.

Aspect 2: The method, apparatus, or non-transitory computer-readable medium of aspect 1, further including operations, features, circuitry, logic, means, or instructions, or any combination thereof for forming one or more openings through the laminated substrate along the singulation line before coupling the first electronic component with the laminated substrate, where formation of each of the one or more openings removes a respective portion of the bus portion.

Aspect 3: The method, apparatus, or non-transitory computer-readable medium of aspect 2, where the respective contact of each of the one or more contact portions is electrically isolated from the one or more ground portions based at least in part on forming the one or more openings.

Aspect 4: The method, apparatus, or non-transitory computer-readable medium of any of aspects 2 through 3, further including operations, features, circuitry, logic, means, or instructions, or any combination thereof for performing a material removal operation through the one or more openings, the material removal operation recessing the one or more contact portions from one or more sidewalls of the one or more openings.

Aspect 5: The method, apparatus, or non-transitory computer-readable medium of any of aspects 1 through 4, where the conductor layer of the laminated substrate further includes one or more second ground portions extending from the bus portion on the second side of the singulation line, where the one or more second ground portions are formed of the continuous conductor material, and where each of the one or more second ground portions has a second width dimension parallel to the singulation line that varies along a distance from the singulation line on the second side of the singulation line; and the second electronic component includes respective portions of the one or more second ground portions based at least in part on dividing the laminated substrate between the first electronic component and the second electronic component.

Aspect 6: The method, apparatus, or non-transitory computer-readable medium of aspect 5, where, for at least one of the one or more ground portions, the width dimension that varies along the distance from the singulation line is associated with one or more first portions having a first width along a respective first length from the singulation line and one or more second portions having a second width, greater than the first width, along a respective second length from the singulation line; and for at least one of the one or more second ground portions, the second width dimension that varies along the distance from the singulation line is associated with one or more third portions having a third width along a respective third length from the singulation line and one or more fourth portions having a fourth width, greater than the third width, along a respective fourth length from the singulation line.

Aspect 7: The method, apparatus, or non-transitory computer-readable medium of aspect 6, where a quantity of the one or more second portions remaining in the first electronic package after dividing the laminated substrate indicates a first extent of the dividing relative to the singulation line, a quantity of the one or more fourth portions remaining in the second electronic package after dividing the laminated substrate indicates a second extent of the dividing relative to respective second contacts of the second electronic package, or both.

Aspect 8: The method, apparatus, or non-transitory computer-readable medium of any of aspects 6 through 7, where dividing the laminated substrate includes a cutting operation using a blade having a width that is less than a minimum distance between one of the one or more second portions and one of the one or more fourth portions.

Aspect 9: The method, apparatus, or non-transitory computer-readable medium of any of aspects 5 through 8, where before dividing the laminated substrate between the first electronic package and the second electronic package, the laminated substrate includes a second conductor layer, opposite the dielectric layer from the conductor layer, including one or more third ground portions extending from the bus portion on the first side of the singulation line and one or more fourth ground portions extending from the bus portion on the second side of the singulation line, where the one or more third ground portions and the one or more fourth ground portions are formed of a second continuous conductor material; each of the one or more third ground portions has a third width dimension parallel to the singulation line that varies along a distance from the singulation line on the first side of the singulation line; each of the one or more fourth ground portions has a fourth width dimension parallel to the singulation line that varies along a distance from the singulation line on the second side of the singulation line; the first electronic component includes respective portions of the one or more third ground portions based at least in part on dividing the laminated substrate between the first electronic component and the second electronic component; and the second electronic component includes respective portions of the one or more fourth ground portions based at least in part on dividing the laminated substrate between the first electronic component and the second electronic component.

Aspect 10: The method, apparatus, or non-transitory computer-readable medium of any of aspects 1 through 9, where dividing the laminated substrate includes operations, features, circuitry, logic, means, or instructions, or any combination thereof for removing a respective portion of each of the one or more ground portions.

Aspect 11: The method, apparatus, or non-transitory computer-readable medium of aspect 10, where a respective width of the one or more ground portions that remains after removing the respective portion indicates a location of the dividing relative to the singulation line.

Aspect 12: The method, apparatus, or non-transitory computer-readable medium of any of aspects 1 through 11, further including operations, features, circuitry, logic, means, or instructions, or any combination thereof for removing a respective portion of each of the one or more contact portions along the singulation line, where the respective contact of each of the one or more contact portions is electrically isolated from the one or more ground portions based at least in part on removing the respective portion of each of the one or more contact portions.

Aspect 13: The method, apparatus, or non-transitory computer-readable medium of any of aspects 1 through 12, further including operations, features, circuitry, logic, means, or instructions, or any combination thereof for plating the respective contact, before coupling the first electronic component with the laminated substrate, with a second conductor material based at least in part on applying a voltage to the bus portion.

Aspect 14: The method, apparatus, or non-transitory computer-readable medium of aspect 13, further including operations, features, circuitry, logic, means, or instructions, or any combination thereof for forming a solder mask over the laminated substrate with one or more openings over the respective contact of each of the one or more contact portions, where the plating of the respective contact of each of the one or more contact portions is performed through the one or more openings.

Aspect 15: The method, apparatus, or non-transitory computer-readable medium of any of aspects 1 through 14, further including operations, features, circuitry, logic, means, or instructions, or any combination thereof for forming, before dividing the laminated substrate, a mold compound over the laminated substrate, where the mold compound covers exposed sidewalls of the one or more contact portions.

Aspect 16: The method, apparatus, or non-transitory computer-readable medium of aspect 15, further including operations, features, circuitry, logic, means, or instructions, or any combination thereof for forming, over the mold compound after dividing the laminated substrate, a conductive shielding layer that is coupled with sidewalls of the one or more ground portions that are exposed based at least in part on the dividing.

Aspect 17: The method, apparatus, or non-transitory computer-readable medium of any of aspects 1 through 16, where after dividing the laminated substrate between the first electronic component and the second electronic component, the one or more ground portions are coupled with a ground node of the first electronic package.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: An electronic package, including: a laminated substrate including a dielectric layer and a conductor layer, the conductor layer including: one or more contacts; and one or more ground portions extending from a sidewall of the laminated substrate, where the one or more contacts are electrically isolated from the one or more ground portions, and where each of the one or more ground portions has a width dimension, parallel to the sidewall of the laminated substrate, that varies along a distance from the sidewall of the laminated substrate; and an electronic component coupled with the laminated substrate, where circuitry of the electronic component is coupled with a respective contact of each of the one or more contacts.

Aspect 19: The electronic package of aspect 18, where a respective width of the one or more ground portions indicates a location of singulation of the electronic package.

Aspect 20: The electronic package of any of aspects 18 through 19, where, for at least one of the one or more ground portions, the width dimension that varies along the distance from the sidewall is associated with one or more first portions having a first width along a respective first length from the sidewall and one or more second portions having a second width, greater than the first width, along a respective second length from the sidewall, and a quantity of the one or more second portions in the electronic package indicates an extent of a cutting operation associated with forming the sidewall.

Aspect 21: The electronic package of any of aspects 18 through 20, where the one or more contacts are associated with a conductor material that is recessed behind one or more sidewalls of the laminated substrate.

Aspect 22: The electronic package of aspect 21, further including: a mold compound over the laminated substrate, the mold compound in contact with the conductor material.

Aspect 23: The electronic package of aspect 22, further including: a shielding layer over the mold compound, the shielding layer coupled with the one or more ground portions.

Aspect 24: The electronic package of any of aspects 18 through 23, where the one or more ground portions are coupled with a ground node of the electronic package.

An apparatus is described. The following provides an overview of aspects of the apparatus as described herein:

Aspect 25: An electronic device formed by a process, including: forming a laminated substrate including a dielectric layer and a conductor layer, the conductor layer including: a bus portion along a singulation line; one or more contact portions extending from the bus portion on a first side of the singulation line; and one or more ground portions extending from the bus portion on the first side of the singulation line, where the bus portion, the one or more contact portions, and the one or more ground portions are formed of a continuous conductor material, and where each of the one or more ground portions has a width dimension, parallel to the singulation line, that varies along a distance from the singulation line; coupling an electronic component with the laminated substrate on the first side of the singulation line, where coupling the electronic component with the laminated substrate includes coupling circuitry of the electronic component with a respective contact of each of the one or more contact portions; and cutting through the laminated substrate along a direction of the singulation line, where the respective contact of each of the one or more contact portions is electrically isolated from the one or more ground portions after cutting through the laminated substrate.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a laminated substrate comprising a dielectric layer and a conductor layer, the conductor layer comprising:
a bus portion along a singulation line;
one or more contact portions extending from the bus portion on a first side of the singulation line; and
one or more ground portions extending from the bus portion on the first side of the singulation line,
wherein the bus portion, the one or more contact portions, and the one or more ground portions are formed of a continuous conductor material, and wherein each of the one or more ground portions has a width dimension, parallel to the singulation line, that varies along a distance from the singulation line;
coupling a first electronic component with the laminated substrate on the first side of the singulation line, wherein coupling the first electronic component with the laminated substrate comprises coupling circuitry of the first electronic component with a respective contact of each of the one or more contact portions;
coupling a second electronic component with the laminated substrate on a second side of the singulation line; and
forming a first electronic package and a second electronic package based at least in part on dividing the laminated substrate between the first electronic component and the second electronic component, wherein the respective contact of each of the one or more contact portions is electrically isolated from the one or more ground portions in the first electronic package.

2. The method of claim 1, further comprising:
forming one or more openings through the laminated substrate along the singulation line before coupling the first electronic component with the laminated substrate, wherein formation of each of the one or more openings removes a respective portion of the bus portion.

3. The method of claim 2, wherein the respective contact of each of the one or more contact portions is electrically isolated from the one or more ground portions based at least in part on forming the one or more openings.

4. The method of claim 2, further comprising:
performing a material removal operation through the one or more openings, the material removal operation recessing the one or more contact portions from one or more sidewalls of the one or more openings.

5. The method of claim 1, wherein:
the conductor layer of the laminated substrate further comprises one or more second ground portions extending from the bus portion on the second side of the singulation line, wherein the one or more second ground portions are formed of the continuous conductor material, and wherein each of the one or more second ground portions has a second width dimension parallel to the singulation line that varies along a distance from the singulation line on the second side of the singulation line; and
the second electronic component comprises respective portions of the one or more second ground portions based at least in part on dividing the laminated substrate between the first electronic component and the second electronic component.

6. The method of claim 5, wherein:
for at least one of the one or more ground portions, the width dimension that varies along the distance from the singulation line is associated with one or more first portions having a first width along a respective first length from the singulation line and one or more second portions having a second width, greater than the first width, along a respective second length from the singulation line; and
for at least one of the one or more second ground portions, the second width dimension that varies along the distance from the singulation line is associated with one or more third portions having a third width along a respective third length from the singulation line and one or more fourth portions having a fourth width, greater than the third width, along a respective fourth length from the singulation line.

7. The method of claim 6, wherein a quantity of the one or more second portions remaining in the first electronic package after dividing the laminated substrate indicates a first extent of the dividing relative to the singulation line, a quantity of the one or more fourth portions remaining in the second electronic package after dividing the laminated substrate indicates a second extent of the dividing relative to respective second contacts of the second electronic package, or both.

8. The method of claim 6, wherein dividing the laminated substrate comprises a cutting operation using a blade having a width that is less than a minimum distance between one of the one or more second portions and one of the one or more fourth portions.

9. The method of claim 5, wherein:
before dividing the laminated substrate between the first electronic package and the second electronic package, the laminated substrate comprises a second conductor layer, opposite the dielectric layer from the conductor layer, comprising one or more third ground portions extending from the bus portion on the first side of the singulation line and one or more fourth ground portions extending from the bus portion on the second side of the singulation line, wherein the one or more third ground portions and the one or more fourth ground portions are formed of a second continuous conductor material;
each of the one or more third ground portions has a third width dimension parallel to the singulation line that varies along a distance from the singulation line on the first side of the singulation line;
each of the one or more fourth ground portions has a fourth width dimension parallel to the singulation line that varies along a distance from the singulation line on the second side of the singulation line;
the first electronic component comprises respective portions of the one or more third ground portions based at least in part on dividing the laminated substrate between the first electronic component and the second electronic component; and
the second electronic component comprises respective portions of the one or more fourth ground portions based at least in part on dividing the laminated substrate between the first electronic component and the second electronic component.

10. The method of claim 1, wherein dividing the laminated substrate comprises:
removing a respective portion of each of the one or more ground portions.

11. The method of claim 10, wherein a respective width of the one or more ground portions that remains after removing the respective portion indicates a location of the dividing relative to the singulation line.

12. The method of claim 1, further comprising:
removing a respective portion of each of the one or more contact portions along the singulation line, wherein the respective contact of each of the one or more contact portions is electrically isolated from the one or more ground portions based at least in part on removing the respective portion of each of the one or more contact portions.

13. The method of claim 1, further comprising:
plating the respective contact, before coupling the first electronic component with the laminated substrate, with a second conductor material based at least in part on applying a voltage to the bus portion.

14. The method of claim 13, further comprising:
forming a solder mask over the laminated substrate with one or more openings over the respective contact of each of the one or more contact portions, wherein the plating of the respective contact of each of the one or more contact portions is performed through the one or more openings.

15. The method of claim 1, further comprising:
forming, before dividing the laminated substrate, a mold compound over the laminated substrate, wherein the mold compound covers exposed sidewalls of the one or more contact portions.

16. The method of claim 15, further comprising:
forming, over the mold compound after dividing the laminated substrate, a conductive shielding layer that is coupled with sidewalls of the one or more ground portions that are exposed based at least in part on the dividing.

17. The method of claim 1, wherein, after dividing the laminated substrate between the first electronic component and the second electronic component, the one or more ground portions are coupled with a ground node of the first electronic package.

18. An electronic package, comprising:
a laminated substrate comprising a dielectric layer and a conductor layer, the conductor layer comprising:
one or more contacts; and
one or more ground portions extending from a sidewall of the laminated substrate,
wherein the one or more contacts are electrically isolated from the one or more ground portions, and wherein each of the one or more ground portions has a width dimension, parallel to the sidewall of the laminated substrate, that varies along a distance from the sidewall of the laminated substrate; and
an electronic component coupled with the laminated substrate, wherein circuitry of the electronic component is coupled with a respective contact of each of the one or more contacts.

19. The electronic package of claim 18, wherein a respective width of the one or more ground portions indicates a location of singulation of the electronic package.

20. The electronic package of claim 18, wherein for at least one of the one or more ground portions, the width dimension that varies along the distance from the sidewall is associated with one or more first portions having a first width along a respective first length from the sidewall and one or more second portions having a second width, greater than the first width, along a respective second length from the sidewall, and a quantity of the one or more second portions in the electronic package indicates an extent of a cutting operation associated with forming the sidewall.

21. The electronic package of claim 18, wherein the one or more contacts are associated with a conductor material that is recessed behind one or more sidewalls of the laminated substrate.

22. The electronic package of claim 21, further comprising:
a mold compound over the laminated substrate, the mold compound in contact with the conductor material.

23. The electronic package of claim 22, further comprising:
a shielding layer over the mold compound, the shielding layer coupled with the one or more ground portions.

24. The electronic package of claim 18, wherein the one or more ground portions are coupled with a ground node of the electronic package.

25. An electronic device formed by a process, comprising:
forming a laminated substrate comprising a dielectric layer and a conductor layer, the conductor layer comprising:
a bus portion along a singulation line;
one or more contact portions extending from the bus portion on a first side of the singulation line; and
one or more ground portions extending from the bus portion on the first side of the singulation line,
wherein the bus portion, the one or more contact portions, and the one or more ground portions are formed of a continuous conductor material, and wherein each of the one or more ground portions has a width dimension, parallel to the singulation line, that varies along a distance from the singulation line;
coupling an electronic component with the laminated substrate on the first side of the singulation line, wherein coupling the electronic component with the laminated substrate comprises coupling circuitry of the electronic component with a respective contact of each of the one or more contact portions; and
cutting through the laminated substrate along a direction of the singulation line, wherein the respective contact of each of the one or more contact portions is electrically isolated from the one or more ground portions after cutting through the laminated substrate.
